(19) United States
(12) Patent Application Publication
(10) Pub. No.: US 2017/0315086 A1
(43) Pub. Date: Nov. 2, 2017

(54) Structures, Apparatuses and Methods for Fabricating Sensors in Multi-Layer Structures

(71) Applicant: Taiwan Semiconductor Manufacturing Company Limited, Hsinchu (TW)

(72) Inventors: Tung-Tsun Chen, Hsinchu (TW); Jui-Cheng Huang, Hsinchu (TW)

(21) Appl. No.: 15/654,777

(22) Filed: Jul. 20, 2017

Related U.S. Application Data
(62) Division of application No. 14/049,284, filed on Oct. 9, 2013.

(51) Int. Cl. G01N 27/414

(52) U.S. Cl. CPC G01N 27/4145; G01N 27/4148; H01L 2924/0002

(57) ABSTRACT

Structures, apparatuses, and methods are provided for fabricating a semiconductor device structure. An example semiconductor device structure includes a first substrate, a first device layer, a second device layer and a third device layer. The first device layer may be on the first substrate and include a switch. The second device layer may be on the first device layer and include a sensing device. The third device layer may include one or more inter-level connection structures configured to electrically connect the switch to the sensing device. The switch may be configured to be electrically turned on in response to a selection signal. The sensing device may be configured to generate an output signal in response to the switch being turned on.

### CROSS-REFERENCE TO RELATED APPLICATION

This is a division of U.S. application Ser. No. 14/049,284, filed Oct. 9, 2013, hereby incorporated herein by reference.

### FIELD

The technology described in this disclosure relates generally to semiconductor devices and more particularly to fabrication of semiconductor devices.

### BACKGROUND

An ion-sensitive field effect transistor (ISFET) generally operates in a manner similar to that of a metal-oxide-semiconductor field effect transistor (MOSFET) and is often configured to selectively measure ion activity in a chemical solution. When the ion concentration (such as hydrogen ions) of the chemical solution changes, the current through the ISFET will change accordingly. For example, the chemical solution is used as a gate electrode.

### SUMMARY

In accordance with the teachings described herein, structures, apparatuses and methods are provided for fabricating a semiconductor device structure. An example semiconductor device structure includes a first substrate, a first device layer, a second device layer and a third device layer. The first device layer may be on the first substrate and include a switch. The second device layer may be on the first device layer and include a sensing device. The third device layer may include one or more inter-level connection structures configured to electrically connect the switch to the sensing device. The switch may be configured to be electrically turned on in response to a selection signal. The sensing device may be configured to generate an output signal in response to the switch being turned on.

In an embodiment, an apparatus includes an array of sensors arranged in rows and columns. A sensor includes a switch and a sensing device. The switch may be formed in a first device layer of a multi-layer semiconductor structure and configured to receive a selection signal. The sensing device may be formed in a second device layer of the multi-layer semiconductor structure. The switch may be configured to enable the sensing device in response to the selection signal. The sensing device may be configured, in response to being enabled, to generate an output signal.

In another embodiment, a method is provided for fabricating a sensor including a sensing device and a switch. For example, a sensing device may be formed in a first device layer on a first substrate. A switch may be formed in a second device layer on a second substrate. One or more inter-level connection structures may be formed in a third device layer on the second device layer. The inter-level connection structures may be disposed to electrically connect to the switch. The first device layer, the third device layer and the second device layer may be stacked together to dispose the inter-level connection structures between the switch and the sensing device. The inter-level connection structures may be disposed to electrically connect to the sensing device.

In yet another embodiment, a method is provided for fabricating a sensor including a sensing device and a switch. For example, a switch may be formed in a first device layer on a substrate. One or more inter-level connection structures may be formed in a second device layer on the first device layer. The inter-level connection structures may be disposed to electrically connect to the switch. A sensing device may be formed in the third device layer on the second device layer. The sensing device may be disposed to electrically connect to the switch through the inter-level connection structures.

### BRIEF DESCRIPTION OF THE DRAWINGS

FIG. 1 depicts an example diagram of a planar front-side ISFET.

FIG. 2 depicts an example diagram of a planar back-side ISFET.

FIG. 3 depicts an example diagram of one or more sensors fabricated in a multi-layer structure.

FIGS. 4A-4D depict example diagrams showing a method for fabricating sensors in the multi-layer structure 300 using two substrates.

FIGS. 5A-5D depict example diagrams showing a method for fabricating sensors in the multi-layer structure 300 using a single substrate.

FIG. 6 depicts an example schematic diagram of a sensor.

FIG. 7 depicts an example diagram of a sensor array.

FIGS. 8A and 8B depict example diagrams of sensor arrays with redundancy arrays.

FIG. 9 depicts an example flow chart for fabricating a sensor including a sensing device and a switch.

FIG. 10 depicts another example flow chart for fabricating a sensor including a sensing device and a switch.

### DETAILED DESCRIPTION

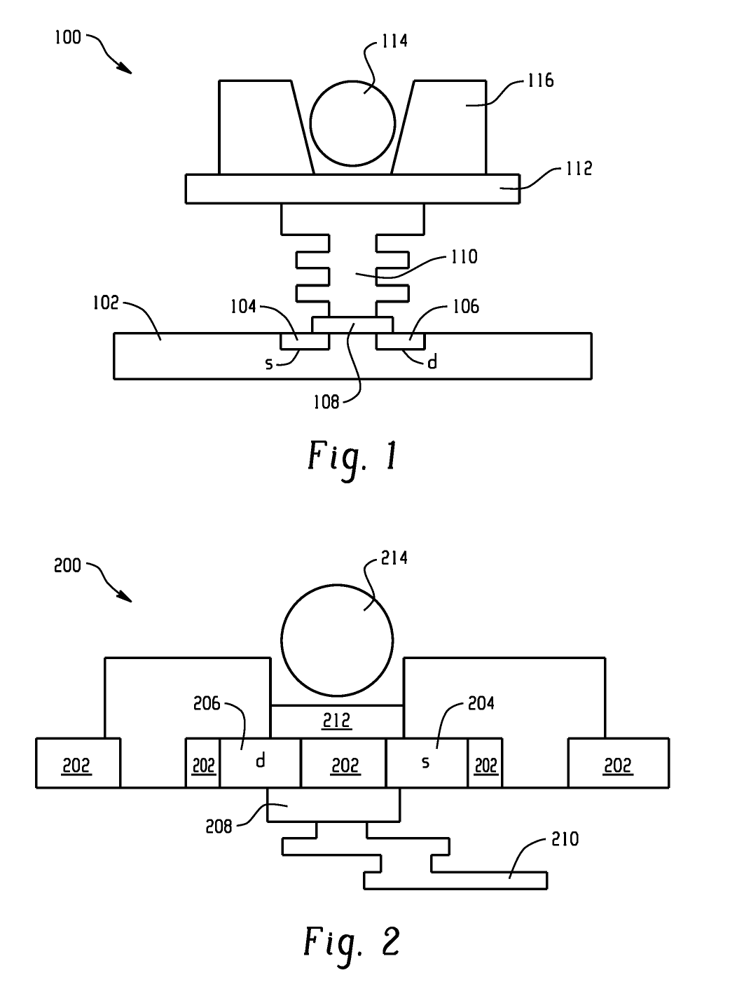

FIG. 1 depicts an example diagram of a planar front-side ISFET. As shown in FIG. 1, the ISFET 100 is fabricated on a substrate 102 (e.g., silicon). Highly doped regions 104 and 106 are formed to serve as a “source” and a “drain” of the ISFET 100, respectively. A dielectric layer 108 (e.g., silicon dioxide) is disposed above the “source” 104 and the “drain” 106 and a gate structure 110 (e.g., polysilicon, metals) is formed on top of the dielectric layer 108. A sensing layer 112 (e.g., silicon nitride) is formed above the gate structure 110 and in contact with a chemical solution. For example, the chemical solution includes one or more DNA molecules. When a DNA molecule 114 moves into a capture structure 116 and is in contact with the sensing layer 112, changes in a surface potential of the sensing layer 112 occur due to a charge (e.g., a positive charge or a negative charge) associated with the DNA molecule 114, which results in a potential shift of the gate structure 110. In turn, a channel current flowing between the regions 104 and 106 of the ISFET 100 is changed, and such a current change may be detected for determining the concentration of the DNA molecules in the chemical solution. In some embodiments, the gate structure 110 includes multiple conductive layers stacked together.

FIG. 2 depicts an example diagram of a planar back-side ISFET. As shown in FIG. 2, the ISFET 200 is fabricated on a wafer 202. Highly doped regions 204 and 206 are formed to serve as a “source” and a “drain” of the ISFET 200, respectively. A dielectric layer 208 is disposed on the back side of the wafer 202, and a gate structure 210 is formed on the dielectric layer 208. A sensing layer 212 (e.g., hafnium oxide) is formed on the front side of the wafer 202 and be in contact with a chemical solution that includes one or more DNA molecules (e.g., the molecule 214).

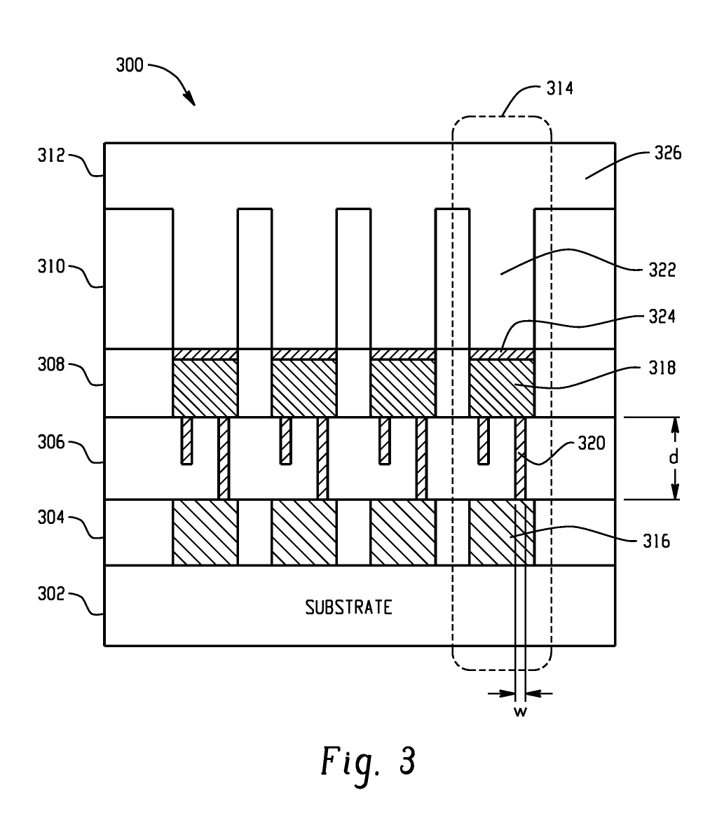

A sensor that includes a sensing device, such as the ISFET 100 and the ISFET 200, and a selective switch is integrated into a multi-layer structure, where the selective switch enables the sensing device in response to at least a selection signal, as shown in FIG. 3.

FIG. 3 depicts an example diagram of one or more exemplary sensors fabricated in a multi-layer structure. As shown in FIG. 3, the multi-layer structure 300 includes a substrate 302, device layers 304, 306, 308, 310, and a channel layer 312. For example, a sensor 314 includes a selective switch 316 formed in the device layer 304, a sensing device 318 formed in the device layer 308, and one or more inter-level connection structures 320 formed in the device layer 306. A well 322 is formed in the device layer 310 (e.g., a dielectric layer) to provide a chemical solution to a sensing layer 324 of the sensing device 318, where the sensing layer 324 is configured to capture ions or protons in the chemical solution. In addition, a channel 326 that connects with the well 322 is formed in the channel layer 312 to receive the chemical solution (e.g., for bio-reaction). For example, the sensing layer 324 includes silicon dioxide, hafnium oxide, silicon nitride, titanium oxide, titanium nitride, aluminum, aluminum oxide, gold, or other materials. As an example, the sensing device 318 includes an ISFET (e.g. the ISFET 100 or the ISFET 200). In another example, the selective switch 316 includes a field effect transistor, a bipolar junction transistor, or other semiconductor devices. In an embodiment, the height of the device layer 306 (e.g., d) is about 5 microns, and the inter-level connection structures 320 has a width of about 3 microns (e.g., w) and a length of about 3 microns (not shown in FIG. 3).

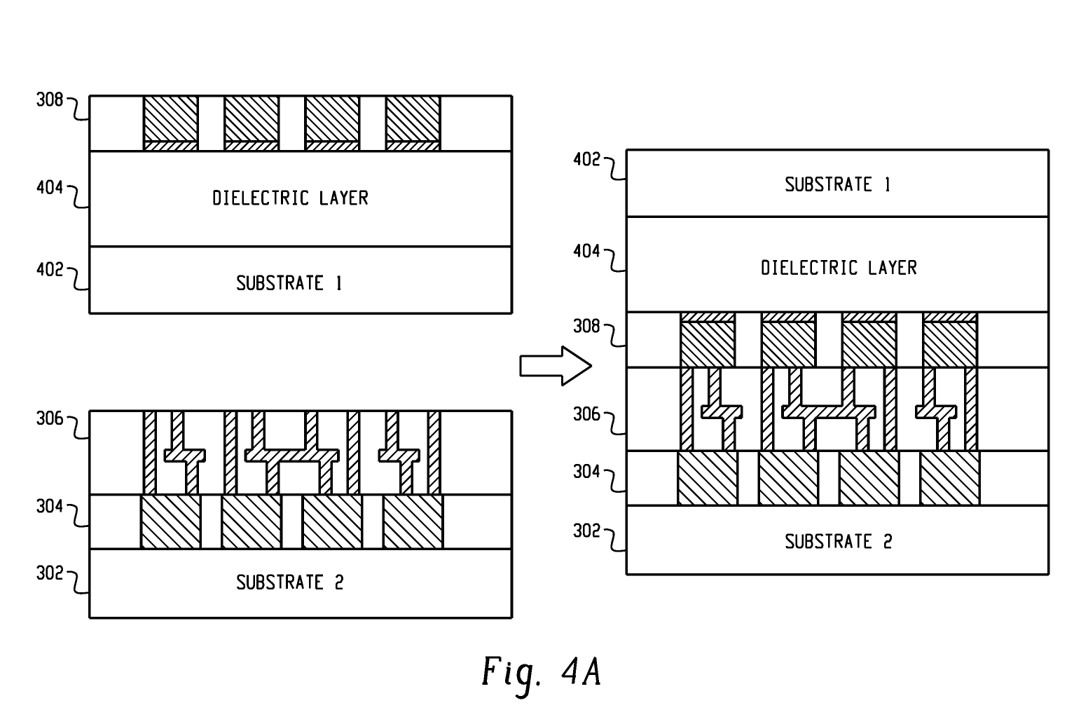

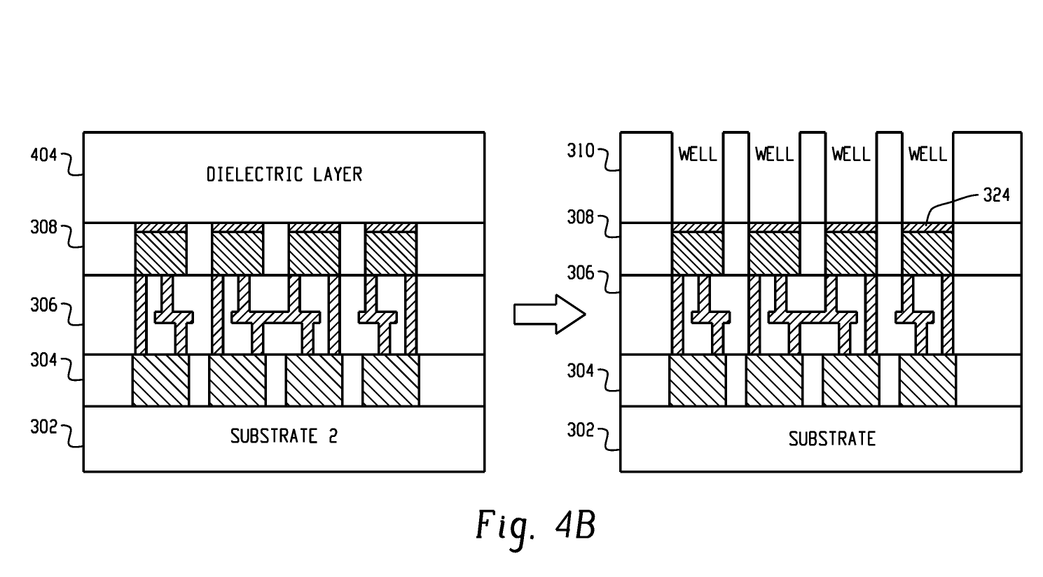

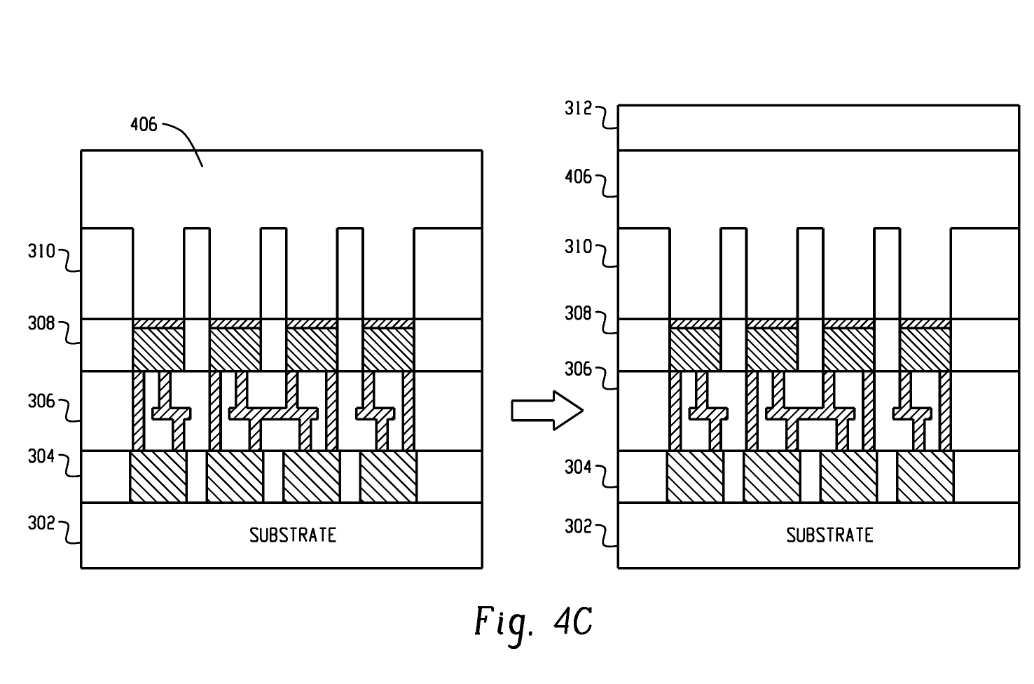

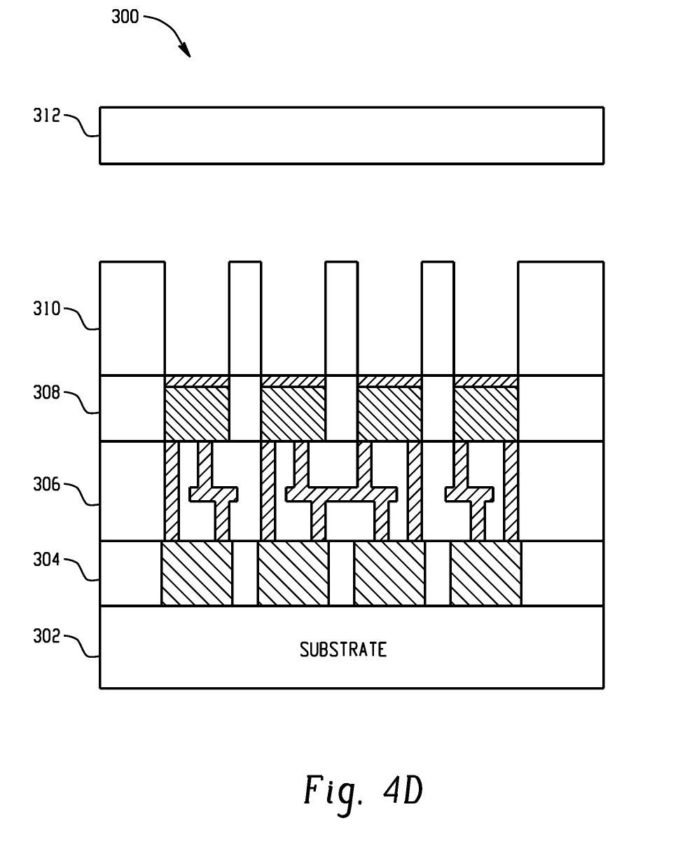

FIGS. 4A-4D depict example diagrams showing an exemplary method for fabricating sensors in the exemplary multi-layer structure 300 using two substrates. As shown in FIG. 4A, the device layer 304 that includes one or more selective switches (e.g., the switch 316) is formed on the substrate 302 (e.g., through epitaxial growth). The device layer 306 that includes one or more inter-level connection structures (e.g., the structure 320) is then formed on the device layer 304 (e.g., through epitaxial growth). On the other hand, the device layer 308 is formed on a dielectric layer 404 on another substrate 402. The device layers 308, 306 and 304 are stacked together (e.g., through wafer bonding).

As shown in FIG. 4B, the substrate 402 in FIG. 4A is removed, and one or more wells are formed in the dielectric layer 404 so that the device layer 310 is formed. For example, the wells in the device layer 310 are formed through lithography patterning and etching, in order to expose the corresponding sensing layers (e.g., the sensing layer 324) to the chemical solution. As shown in FIG. 4C, a sacrificial layer 406 is formed on the device layer 310, and the channel layer 312 is formed on the sacrificial layer 406 to define one or more channels. Then, as shown in FIG. 4D, the sacrificial layer 406 is released, e.g., by etching or other methods.

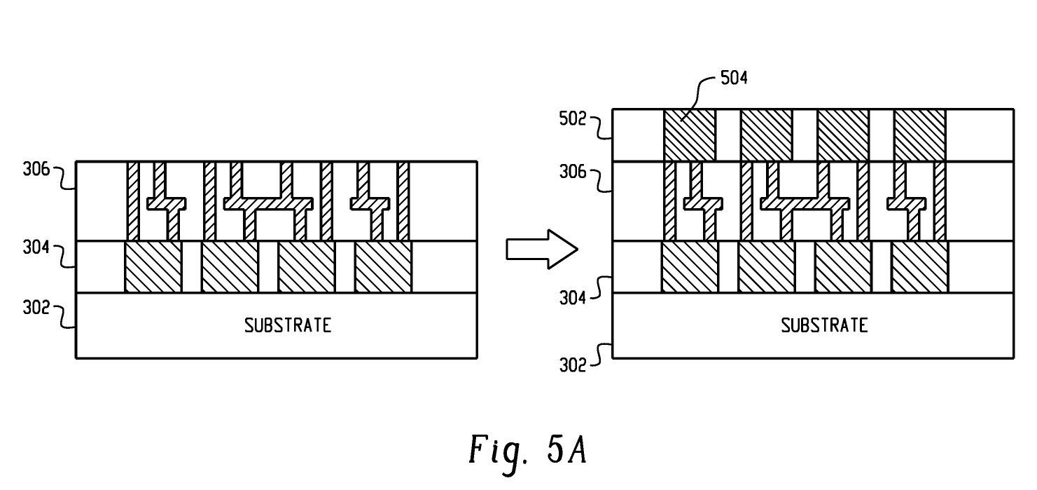

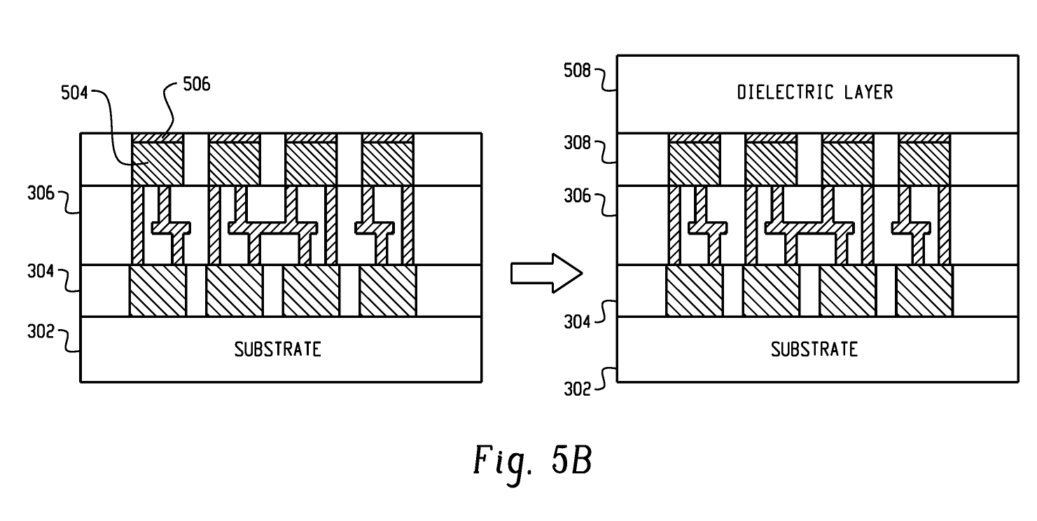

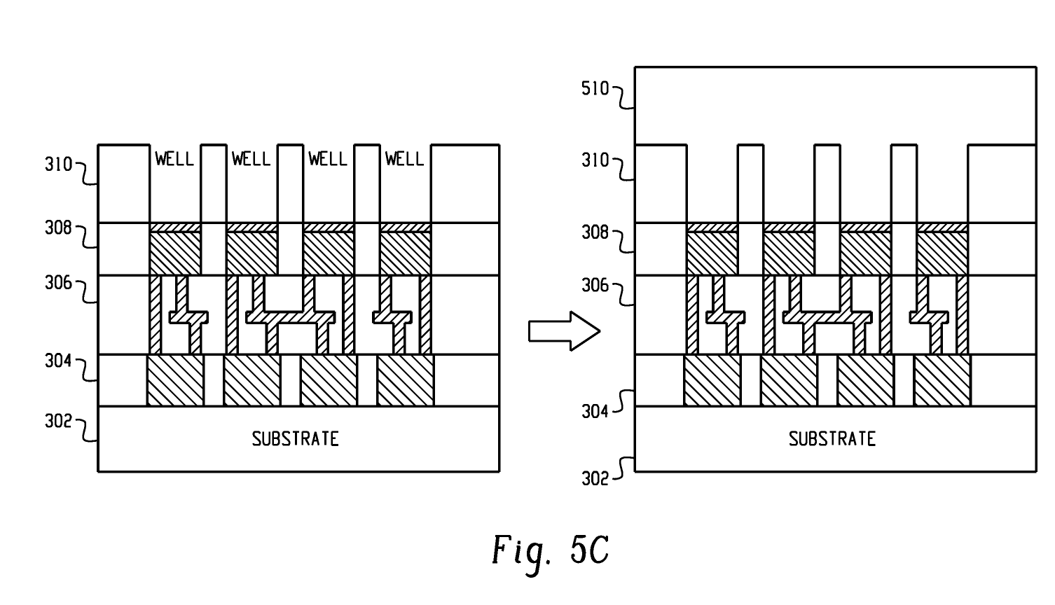

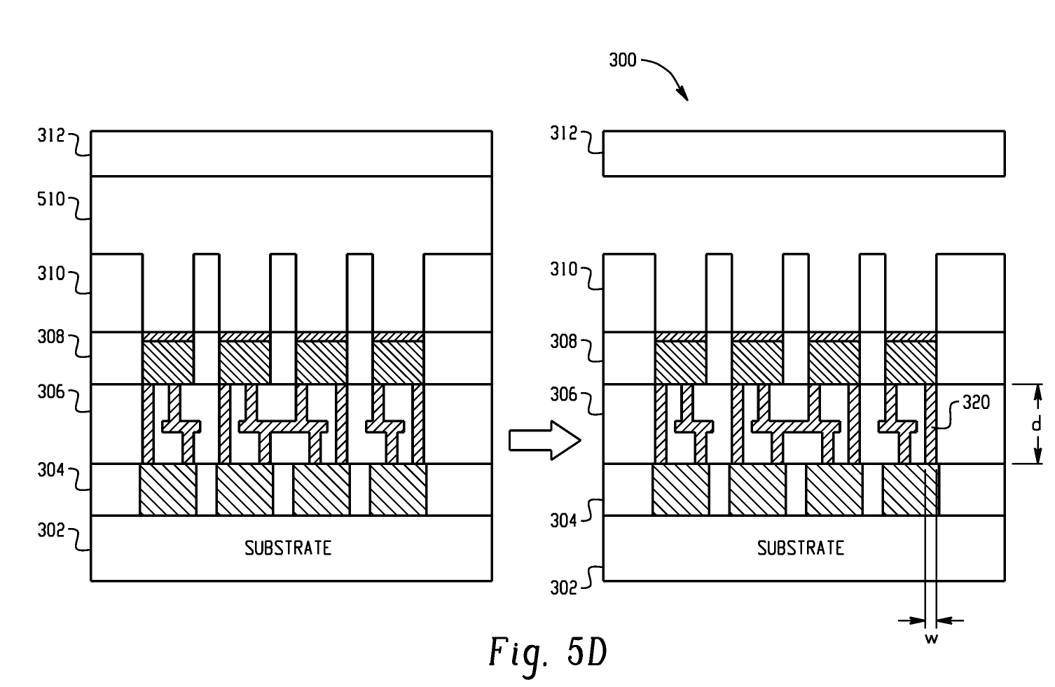

FIGS. 5A-5D depict example diagrams showing an exemplary method for fabricating sensors in the multi-layer structure 300 using a single substrate. As shown in FIG. 5A, the device layer 304 that includes one or more selective switches (e.g., the switch 316) is formed on the substrate 302, and the device layer 306 that includes one or more inter-level connection structures (e.g., the structure 320) is formed on the device layer 304 (e.g., through epitaxial growth). Then, a thin semiconductor layer 502 (e.g., silicon) is formed on the device layer 306, and one or more sensing device structures (e.g., the device structure 504) are patterned for ion sensing. As shown in FIG. 5B, one or more sensing layers (e.g., the sensing layer 506) are deposited on the sensing device structures (e.g., the device structure 504) so that the device layer 308 is formed. Subsequently, a dielectric layer 508 is formed on the device layer 308. One or more wells are formed in the dielectric layer 508 to form a device layer, such as the device layer 310 as shown in FIG. 5C. For example, the wells in the device layer 310 are formed through lithography patterning and etching.

As shown in FIG. 5C, a sacrificial layer 510 is formed on the device layer 310. Then, as shown in FIG. 5D, the channel layer 312 is formed on the sacrificial layer 510, and the sacrificial layer 510 is released, e.g., by etching or other methods. For example, the height of the device layer 306 (e.g., d) is about 0.1 micron. As an example, the inter-level connection structures 320 has a width (e.g., w) of about 0.3 micron and a length (not shown in FIG. 5D) of about 0.3 micron.

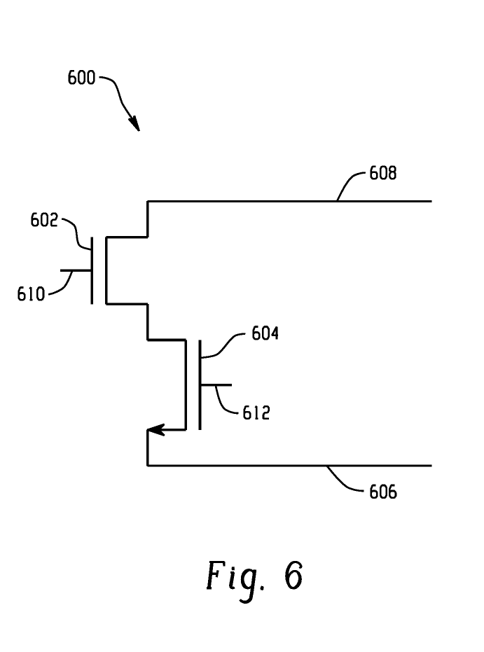

FIG. 6 depicts an example schematic diagram of a sensor 600. The sensor 600 includes a selective switch 602 and a sensing device 604. In some embodiments, the sensor 600 is the same as the sensor 314 as shown in FIG. 3. As shown in FIG. 6, the selective switch 602 is closed (i.e., being turned on) in response to a selection signal 608 in combination with a gate signal 610, and the sensing device 604 is then enabled in response to a gate signal 612. Once enabled, the sensing device 604 facilitates the measurement of an ion concentration of a chemical solution. In an embodiment, the sensing device 604 changes a source voltage 606 (e.g., common to an array of sensors) to indicate ion detection. The switch 602 includes a field effect transistor, a bipolar junction transistor, or other types of transistors. The sensing device 604 includes an ISFET or other types of transistors.

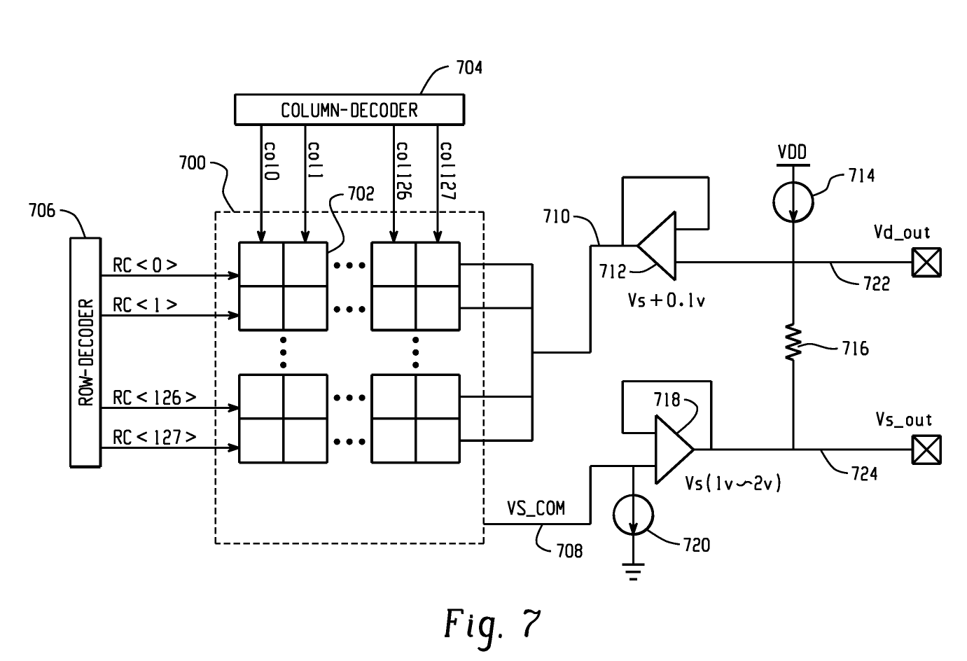

FIG. 7 depicts an example diagram of a sensor array. As shown in FIG. 7, the sensor array 700 includes, for example, 128 columns and 128 rows. A sensor in the array corresponds to a particular column and a particular row. For example, the sensor 702 corresponds to column “1” and row “0.” In an embodiment, a column decoder 704 provides a column selection signal to the sensors in the array 700, and a row decoder 706 provides a row selection signal to the sensors. For example, a selective switch within a particular sensor is electrically turned on (e.g., being closed) in response to a selection signal, and in turn enable a sensing device within the particular sensor. A source voltage 708 is output by the sensor array 700 to indicate ion detection of a chemical solution.

In some embodiments, a current-source component 714 in combination with a resistor 716 determines a voltage difference (e.g., about 0.1 V) between two signals 722 and 724 (e.g., Vₛ). The sensor array 700 receives a bias signal 710 from an amplifier 712 which receives the signal 722. The source voltage 708 is provided to another amplifier 718 and a current-source component 720, and affects the signal 724 (e.g., about 1-2 V).

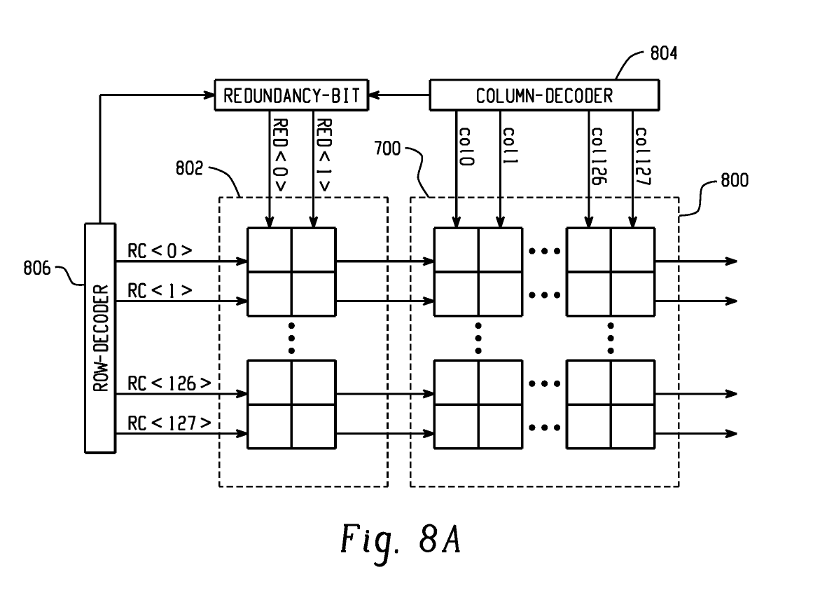

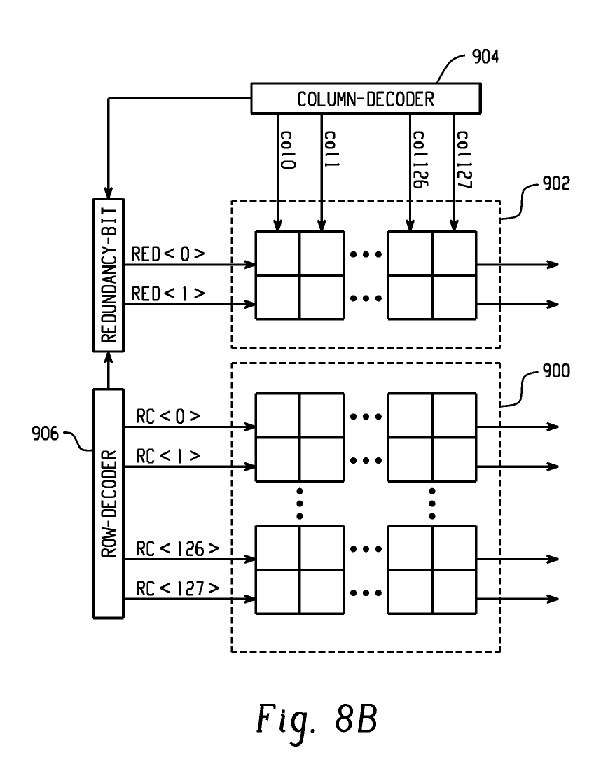

FIGS. 8A and 8B depict example diagrams of sensor arrays with redundancy arrays. As shown in FIG. 8A, a column redundancy array 802 is provided for a sensor array 800 (e.g., including 128×128 sensors). For example, the column redundancy array 802 includes another sensor array (e.g., including 2×128 sensors). When certain sensors in the sensor array 800 fail, a column decoder 804 and a row decoder 806 detect and disable the failed sensors, and enable one or more sensors in the column redundancy array 802 as replacements. Similarly, as shown in FIG. 8B, a row redundancy array 902 is provided for a sensor array 900 (e.g., including 128×128 sensors). For example, the row redundancy array 902 includes a sensor array (e.g., including 128×2 sensors). When certain sensors in the sensor array 900 fail, a column decoder 904 and a row decoder 906 detect and disable the failed sensors, and enable one or more sensors in the row redundancy array 902 as replacements.

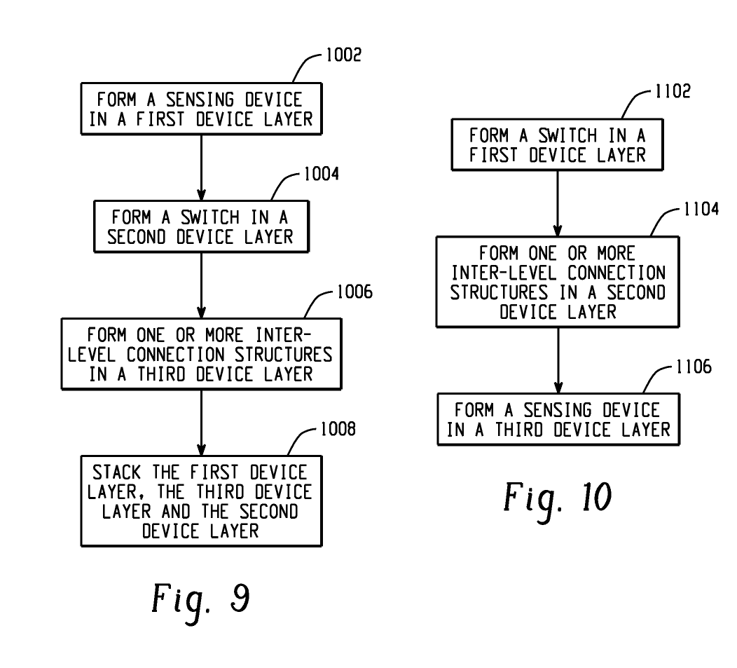

FIG. 9 depicts an example flow chart for fabricating an exemplary sensor including a sensing device and a switch. For example, at 1002, a sensing device (e.g., the sensing device 318) is formed in a first device layer (e.g., the device layer 308) on a first substrate (e.g., the substrate 402). At 1004, a switch (e.g., the switch 316) is formed in a second device layer (e.g., the device layer 304) on a second substrate (e.g., the substrate 302). At 1006, one or more inter-level connection structures are formed in a third device layer (e.g., the device layer 306) on the second device layer. The inter-level connection structures are disposed to electrically connect to the switch. At 1008, the first device layer, the third device layer and the second device layer are stacked together to dispose the inter-level connection structures between the switch and the sensing device. The inter-level connection structures are disposed to electrically connect to the sensing device.

FIG. 10 depicts another example flow chart for fabricating an exemplary sensor including a sensing device and a switch. For example, at 1102, a switch (e.g., the switch 316) is formed in a first device layer (e.g., the device layer 304) on a substrate (e.g., the substrate 302). At 1104, one or more inter-level connection structures (e.g., the structures 320) are formed in a second device layer (e.g., the device layer 306) on the first device layer. The inter-level connection structures are disposed to electrically connect to the switch. At 1106, a sensing device (e.g., the sensing device 318) is formed in the third device layer (e.g., the device layer 308) on the second device layer. The sensing device is disposed to electrically connect to the switch through the inter-level connection structures.

Depending upon embodiments, one or more benefits may be achieved. These benefits and various additional objects, features and advantages of the embodiments of the present disclosure can be fully appreciated with reference to the detailed description and the accompanying drawings. For example, fabricating a sensor (e.g., the sensor 314) in a multi-layer structure (e.g., the structure 300) reduces the size of the sensor and thus increases the number of sensors in a sensor array for a given semiconductor die. In addition, the signal-to-noise ratio (SNR) of the sensor is improved, and the parasitic capacitance and/or the parasitic resistance associated with a gate structure of the sensing device are reduced.

This written description uses examples to disclose embodiments of the disclosure, include the best mode, and also to enable a person of ordinary skill in the art to make and use various embodiments of the disclosure. The patentable scope of the disclosure may include other examples that occur to those of ordinary skill in the art. One of ordinary skill in the relevant art will recognize that the various embodiments may be practiced without one or more of the specific details, or with other replacement and/or additional methods, materials, or components. Well-known structures, materials, or operations may not be shown or described in detail to avoid obscuring aspects of various embodiments of the disclosure. Various embodiments shown in the figures are illustrative example representations and are not necessarily drawn to scale. Particular features, structures, materials, or characteristics may be combined in any suitable manner in one or more embodiments. Various additional layers and/or structures may be included and/or described features may be omitted in other embodiments. Various operations may be described as multiple discrete operations in turn, in a manner that is most helpful in understanding the disclosure. However, the order of description should not be construed as to imply that these operations are necessarily order dependent. In particular, these operations need not be performed in the order of presentation. Operations described herein may be performed in a different order, in series or in parallel, than the described embodiments. Various additional operations may be performed and/or described. Operations may be omitted in additional embodiments.

This written description and the following claims may include terms, such as left, right, top, bottom, over, under, upper, lower, first, second, etc. that are used for descriptive purposes only and are not to be construed as limiting. For example, terms designating relative vertical position may refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and may still fall within the meaning of the term “top.” The term “on” as used herein (including in the claims) may not indicate that a first layer “on” a second layer is directly on and in immediate contact with the second layer unless such is specifically stated; there may be a third layer or other structure between the first layer and the second layer on the first layer. As an example, the structures, layouts, materials, operations, voltage levels, or current levels related to “source” and “drain” described herein (including in the claims) may be interchangeable as a result of transistors with “source” and “drain” being symmetrical devices. The term “substrate” may refer to any construction comprising one or more semiconductive materials, including, but not limited to, bulk semiconductive materials such as a semiconductive wafer (either alone or in assemblies comprising other materials thereon), and semiconductive material layers (either alone or in assemblies comprising other materials). The embodiments of a device or article described herein can be manufactured, used, or shipped in a number of positions and orientations. Persons of ordinary skill in the art will recognize various equivalent combinations and substitutions for various components shown in the figures.

1. A method comprising:
forming a switch layer that includes switches;
forming, on the switch layer, a connection layer that includes inter-level connection structures;
forming, on a dielectric layer, a sense layer that includes sensing devices; and
after the connection layer is formed on the switch layer and the sense layer is formed on the dielectric layer, joining the sense layer to the connection layer such that the inter-level connection structures electrically connect the sensing devices to the switches.

2. The method of claim 1, wherein the connection layer is formed on the switch layer through epitaxial growth.

3. The method of claim 1, wherein the joining is performed by wafer bonding the sensing-layer to the connection layer.

4. The method of claim 1, wherein inter-level connection structures are electrically connected to the switches prior to the adjoining.

5. The method of claim 1, wherein the sense layer has a top surface that is on an opposite side of the sense layer from the dielectric layer, and the connection layer has a top surface that is on an opposite side of the connection layer from the switch layer, and the adjoining includes contacting the sense layer's top surface to the connection layer's top surface.

6. The method of claim 1, wherein the adjoining includes inverting the sense layer.

7. The method of claim 1, further comprising:
forming the dielectric layer on a substrate; and
removing the substrate from the dielectric layer after the joining.

8. The method of claim 1, further comprising, after the joining:
etching, above each sensing device, a well that extends completely through the dielectric layer to the respective sensing device.

9. The method of claim 8, further comprising:
forming a sacrificial layer that fills the wells and extends upward to a level higher than the dielectric layer.

10. The method of claim 9, further comprising:
forming a channel layer on the sacrificial layer, such that the channel layer is spaced above the dielectric layer by the sacrificial layer.

11. The method of claim 10, further comprising:
removing the sacrificial layer, leaving the channel layer spaced above the dielectric layer.

12. A method comprising:
forming a switch layer that includes switches;
forming, on the switch layer, a connection layer that includes inter-level connection structures;
forming, on the connection layer, a sense layer that includes sensing devices; and
forming a dielectric layer on the sense layer.

13. The method of claim 12, further comprising:
etching, above each sensing device, a well that extends completely through the dielectric layer to the respective sensing device.

14. The method of claim 13, further comprising:
forming a sacrificial layer that fills the wells and extends upward to a level higher than the dielectric layer.

15. The method of claim 14, further comprising:
forming a channel layer on the sacrificial layer, such that the channel layer is spaced above the dielectric layer by the sacrificial layer.

16. The method of claim 15, further comprising:
removing the sacrificial layer, leaving the channel layer spaced above the dielectric layer.

17. A method comprising:
forming a structure that includes a dielectric layer on a sense layer, wherein the sense layer includes sensing devices;
etching, above each sensing device, a well that extends completely through the dielectric layer to the respective sensing device; and
forming a sacrificial layer that fills the wells and extends upward to a level higher than the dielectric layer.

18. The method of claim 17, further comprising:
forming a channel layer on the sacrificial layer, such that the channel layer is spaced above the dielectric layer by the sacrificial layer.

19. The method of claim 18, further comprising:
removing the sacrificial layer, leaving the channel layer spaced above the dielectric layer.

20. The method of claim 17, wherein the structure includes, prior to etching the wells, a connection layer underlying the sense layer and a switch layer underlying the connection layer, wherein the switch layer includes switches, and the connection layer includes inter-level connection structures that electrically connect the sensing devices to the switches.
